(19) United States
(12) Patent Application Publication
(10) Pub. No.: US 2025/0197720 A1
(43) Pub. Date: Jun. 19, 2025

(54) LUMINESCENT DIAMOND WITH NEGATIVELY CHARGED VACANCIES

(71) Applicant: Schlumberger Technology Corporation, Sugar Land, TX (US)

(72) Inventor: Yahua Bao, Orem, UT (US)

(21) Appl. No.: 18/851,194

(22) PCT Filed: May 26, 2023
(86) PCT No.: PCT/US2023/023697

§ 371 Date: Sep. 26, 2024

Related U.S. Application Data
(60) Provisional application No. 63/365,433, filed on May 27, 2022.

(51) Int. Cl. C09K 11/65; B01J 3/06

(52) U.S. Cl. CPC C09K 11/65; B01J 3/062

(57) ABSTRACT

Luminescent materials have red luminescent behavior after sintering using an HPHT process. Red luminescence is achieved with a temperature of 1475° C. to 1800° C. and potentially 1600° C. to 1750° C. with coarse sintered diamond powder having an average size greater than or equal to 100 nm. or more fine grain average grain sizes of at least 25 nm or at least 50 nm. The luminescent material has red luminescence as a result of NV⁻ centers created through the HPHIT process which dominates over NV⁰ centers produced at lower temperatures. and over NVN centers produced at higher temperatures.

### CROSS REFERENCE TO RELATED APPLICATION

This application claims the benefit of U.S. Provisional Application No. 63/365,433, entitled “LUMINESCENT DIAMOND WITH NEGATIVELY CHARGED VACANCIES,” filed May 27, 2022, the disclosure of which is hereby incorporated herein by reference.

### BACKGROUND

Laser-infused fluorescence is a known technique adopted for better understanding how biological systems function at a molecular level through the probing of biomolecules individually for observation. In an example, laser-infused fluorescence may be applied to image and track a single molecule or particle in a biological cell or the like, e.g., in-vivo biological sensors for internal organ mapping, cell imaging, and the like. One type of substance used for laser-infused fluorescence is luminescent nanodiamond, which is nano-sized diamond particles or grains that has been developed to emit light when excited by a light source within a desired wavelength as called for by the end-use application.

### SUMMARY

Luminescent diamond and methods of making the same are disclosed herein, and include subjecting a volume of precursor diamond grains to a high-pressure/high-temperature (HPHT) condition to cause the grains to undergo plastic deformation to produce nitrogen vacancy defects in the diamond grains, that increases the luminescent activity and intensity of the resulting diamond material as compared to that of the precursor diamond grains. In some embodiments, the HPHT condition is performed at an elevated temperature between 1475° C. and 1800° C., or between 1600° C. and 1750° C., which causes diamond grains to undergo plastic deformation and preferentially produce negatively charged nitrogen vacancy (NV⁻) defects in the diamond grains, thereby resulting in a higher display of luminescence intensity in a red wavelength spectrum.

In some embodiments, the luminescent diamond material formed by the HPHT process includes diamond particles that are mechanically interlocked together and combined with a pressure transfer media. The luminescent diamond material displays a level of red luminescence greater than that of precursor diamond material used to form the luminescent diamond material as a result of a higher ratio of negatively charged nitrogen vacancies (NV⁻) to either or both of neutral charge nitrogen vacancies (NV⁰) and NVN defects.

This summary is provided to introduce a selection of concepts that are further described below in the detailed description. This summary is not intended to identify key or essential features of the claimed subject matter, nor is it intended to be used as an aid in limiting the scope of the claimed subject matter.

### BRIEF DESCRIPTION OF THE DRAWINGS

Features and aspects of luminescent nanodiamond and methods of making the same as disclosed herein will be appreciated as the same becomes better understood by reference to the detailed description and appendix when considered in connection with the accompanying drawings where:

FIG. 1-1 is a graph illustrating luminescence intensity and wavelength information for diamond powder sintered at different elevated temperatures, and when excited with a laser emitting light at 473 nm, according to an embodiment of the present disclosure;

FIG. 1-2 is a graph illustrating luminescence intensity and wavelength information for diamond powder sintered at other, different elevated temperatures, and when excited with a laser emitting light at 473 nm, according to an embodiment of the present disclosure;

FIG. 2-1 is a graph illustrating the effect of sintering temperature on red luminescence intensity when diamond powder is excited with a laser emitting light at 532 nm, according to an embodiment of the present disclosure;

FIG. 2-2 is a graph illustrating luminescence intensity and wavelength information for diamond powder sintered at 1475° C. and when excited with a laser emitting light at 532 nm, according to an embodiment of the present disclosure;

FIG. 3 is a graph illustrating luminescence intensity and wavelength information for diamond powder sintered at different elevated temperatures, and when excited with a laser emitting light at 532 nm, according to an embodiment of the present disclosure;

FIG. 4 is a graph illustrating luminescence intensity and wavelength information for diamond powder sintered at different elevated temperatures, and when excited with a laser emitting light at 473 nm, according to an embodiment of the present disclosure;

FIG. 5 is a graph illustrating luminescence intensity and wavelength information for diamond powder sintered at different elevated temperatures, and when excited with a laser emitting light at 532 nm, according to an embodiment of the present disclosure; and

FIG. 6 is a block diagram illustrating processing steps for making luminescent diamond as disclosed herein.

### DETAILED DESCRIPTION

In some embodiments, luminescent diamond (e.g., photoluminescent diamond) and methods for making the same as disclosed herein is engineered in a manner that increases manufacturing efficiency and manufacturing volume to thereby improve affordability and availability of the substance for end-use applications including and not limited to use in optically detected magnetic resonance (ODMR). Further, in some embodiments, luminescent diamond as prepared in accordance with the principles disclosed herein display a level of luminescence intensity that is similar to or greater than that of conventional luminescent diamond, to thereby present an opportunity for expanding the range of potential end-use applications for such material. For instance, techniques may be sufficiently powerful in connection with ODMR to enhance sensitivity of spin resonance spectroscopy by several orders of magnitude.

For purposes of clarity, in some embodiments luminescent diamond as disclosed herein is formed initially by consolidation and compaction of pre-existing diamond grains, forming a luminescent active sintered body or slug (characterized by a high degree of intercrystalline diamond bonding), or forming a mechanically combined semi-sintered body or slug (characterized by substantially no intercrystalline diamond bonding). In such condition, the consolidated material may be referred to as luminescent diamond. During a subsequent procedure the luminescent diamond is reduced in size as called for by a particular end use, and in some embodiments, the resulting diamond particles or grains are nano-scale in size. In some embodiments, the reduced sized luminescent diamond may be exclusively nano-size particles or may include a combination of nano-size particles with coarser diamond particles. The term “nanodiamond” as used herein is understood to refer to diamond particles having an average size between 1 nm and 1000 nm. While the existence of luminescent nanodiamond may be known, the methods and techniques currently used to make such luminescent nanodiamond are expensive, energy and time intensive, adding to not only the cost of the substance but limiting the availability of the same. In some embodiments, by making luminescent diamond as disclosed herein, any combination of cost, energy, or time may be reduced.

In some embodiments, luminescent nanodiamond as disclosed herein may be formed by combining a volume of precursor diamond grains, which may be in the form of natural and/or synthetic diamond grains, and placing the volume of diamond grains into a can or container. In some embodiments, the raw diamond grains of the precursor material may have an average grain size of any value or range between 15 nm and 1000 μm. For instance, the average grain size may be from 1 nm to 1000 μm, from 5 nm to 500 μm, from 5 nm to 100 μm, from 5 nm to 50 μm, from 5 nm to 1 μm, from 5 nm to 500 nm, from 5 nm to 200 nm, from 25 nm to 500 nm, from 5 nm to 30 nm, from 30 nm to 90 nm, from 75 nm to 500 nm, from 75 nm to 250 nm, or any other values or ranges therein. The precursor diamond grain or powder sizes may therefore extend in some embodiments into the submicron or nanodiamond range. In some embodiments, nanosized powders formed either by mechanical crushing of conventional diamond powders or detonation processes can be employed in a similar manner. The diamond powders can either be of synthetic or natural origin; however, synthetic diamond powder can generally have a higher intrinsic nitrogen content, which, along with an adjacent vacancy, makes the diamond luminescent active.

In some embodiments, it is desired that the starting diamond material have an intrinsic amount of nitrogen impurity that is consistent with that found in diamond designated as type 1b (e.g., 50 ppm nitrogen or higher). Nanopowders synthesized through shock synthesis generally have higher intrinsic nitrogen content as well. In some embodiments, the container and its contents are subjected to a high-pressure/high-temperature (HPHT) consolidation process using conventional press equipment for making polycrystalline diamond. In some embodiments, the volume of diamond grains is placed into the can or container, and the can or container may or may not be sealed and is placed within a HPHT press and subjected to desired sintering pressure and temperature conditions. In some embodiments, the HPHT process temperature may be in the range of from 1300° C. to 2500° C., and the process pressure may be from 3.0 GPa to 10 GPa. In some embodiments, the volume of diamond grains is substantially free of any catalyst material, so that diamond material resulting from the HPHT process is not fully sintered, but rather is in the form of a semi-sintered slug or body including diamond grains that are mechanically combined together by frictional contact, cold welding, diamond self-diffusion, and the like. In some embodiments, producing a diamond material that is not fully sintered, i.e., that is semi-sintered and not characterized by a network of bonded-together diamond grains making use of a conventional metal solvent catalyst, the relative transparency of the same as contrasted with a sintered polycrystalline diamond body is improved, and the transparency may improve the intensity of luminescent emission therefrom. There may also be graphite that forms in the porous regions of the semi-sintered body, which may decrease the intensity of the luminescence. In such case it is desired that the graphitic material be partially of completely removed as part of the manufacturing process.

During the HPHT process, it has been discovered that at least a portion of the volume of precursor diamond grains undergoes plastic deformation. In some embodiments, the extent of the HPHT consolidation process is such to cause sufficient plastic deformation in the diamond grains to create nitrogen vacancy (NV and/or NVN) defects and/or N3 optical centers in the diamond grains that operate to make the diamond grains luminescent active. Plastic deformation of diamond particles during HPHT is believed to create vacancies as deformation mechanisms such as crystallographic dislocation motions become active, which vacancies can in turn combine with nitrogen impurities to form the NV, NVN, or N3 centers which create the desired luminescent activity. In some embodiments, this occurs during conventional sintering of polycrystalline diamond with metal catalysts (such as cobalt that function to promote intercrystalline diamond bonding during the HPHT process) or non-metal catalysts/pressure transfer media (such as carbonates and chlorides that do not promote intercrystalline diamond bonding during the HPHT process. In some embodiments, the diamond grains resulting from the HPHT process may be heavily plastically deformed with extensive NV, NVN defects, and/or N3 centers, and weak diamond-diamond bonding in comparison to solvent catalyst bonded polycrystalline diamond. For example, in some embodiments, the diamond grains incur such plastic deformation giving rise to luminescent activity during the HPHT process without resulting in a fully-sintered body, thereby making the downstream process of sizing the diamond grains, by a crushing process or the like, easier and less energy intensive, as primarily or only breaking apart mechanically combined diamond grains is required.

In some embodiments, luminescent diamond as disclosed herein may be formed by subjecting a volume of diamond precursor grains to an HPHT process in the presence of a catalyst material. In such embodiments, the type of catalyst materials used may be selected from a group including and not limited to Co, Fe, Ni, carbonates, Si and combinations thereof for forming polycrystalline diamond (PCD). In some embodiments, HPHT processing conditions for cobalt PCD may be within a temperature of from 1300° C. to 1500° C. and pressures from 5.0 GPa to 7.5 GPa. In addition, cobalt PCD can be heat treated in vacuum at temperatures of 600° C. to 700° C. (e.g., after PCD formation, before and/or after sizing).

The amount of the catalyst material used can and will vary depending on such factors as the type of catalyst used, the amount of luminescence desired, the sintering temperature, and the particular end-use application. In biological end-use applications, for biocompatibility reasons, the presence of a metal material in the luminescent diamond may not be desired and/or permitted, in which case it may be desired to use a non-metallic catalyst. In some embodiments, using a non-metallic catalyst results in a PCD body having relatively higher transparency or reduced opacity when compared to PCD formed using a metal solvent catalyst. In some embodiments, non-metallic catalysts useful for making luminescent diamond as disclosed herein include carbonate catalysts such as sodium carbonate, magnesium carbonate, calcium carbonate, or the like, resulting in the formation of carbonate PCD (CPCD).

In some embodiments, the amount of such carbonate catalyst may be an amount sufficient to form a completely sintered carbonate PCD body (e.g., up to 5% by weight based on the total weight of the carbonate catalyst and the diamond grains). Carbonate PCD appears to be intrinsically less dark/more transparent than cobalt PCD, which is believed to contribute to a higher level of luminescent emission and intensity. In some embodiments, HPHT processing of carbonate PCD may be at temperatures of from 1000° C. to 2500° C. (e.g., 1400° C. to 2100° C., 1500° C. to 1800° C., or 1600° C. to 1750° C.) and at pressures greater than 6 GPa or greater than 7.0 GPa. In addition, carbonate PCD may be heat treated in an inert or vacuum environment to temperatures of 500° C. to 1300° C. (e.g., after formation, before and/or after sizing). In other examples, fluoride or chloride catalysts may be used as pressure media (e.g., sodium fluoride/chloride, magnesium fluoride/chloride, calcium fluoride/chloride, etc.) in suitable quantities and HPHT processing conditions.

As with embodiments described herein, HPHT processing produces plastic deformations in the diamond grains creating NV, NVN, and/or N3 centers that give rise to an increased level of luminescent activity/intensity as compared to the precursor diamond grains. Some vacancies formed during HPHT may not combine with nitrogen during the plastic deformation process and may migrate adjacent to nitrogen sites during heat treatment, creating additional NV, NVN, and/or N3 sites. The higher processing temperature and pressure conditions involved with carbonate PCD may produce a higher degree of plastic deformation in the diamond grains, and therefore produce higher luminescence activity. The use of higher heat treating temperatures may also contribute to additional NV, NVN, and/or N3 centers, and therefore higher luminescent activity.

In some embodiments, it may be desired that the amount of catalyst material used be less that that useful to form a completely sintered PCD body (e.g., less than 5% by weight catalyst compared to the total weight of the diamond layer or PCD body). In such embodiments, it may be desired to produce a partially-sintered or semi-sintered PCD body that includes both intercrystalline bonded diamond and free diamond grains for the purpose of easing the downstream process of sizing the PCD body into nanosized diamond pieces or grains. It has been discovered that PCD made in the manner disclosed herein produces a level of luminescence intensity that is greater than that of conventional luminescent nanodiamond, and for this reason, producing a product during HPHT processing that has some PCD even if not producing a fully-sintered diamond body, may provide desired increases in luminescence intensity while also making the downstream process of sizing relatively easier and less energy intensive than one involving a fully-sintered PCD body. Thus, by adjusting the amount of catalyst material, a diamond material having a desired degree of sintering that yields a desired increase in luminescence intensity may also ease the downstream sizing process.

In still further cases, it has been observed that the luminescence in certain wavelengths may be further improved by controlling the processing conditions. For instance, NV centers in diamond create can give rise to red luminescence (e.g., with a peak centered at about 650 nm), NVN centers in diamond can give rise to green luminescence (e.g., with a peak centered at about 525 nm), and N3 centers in diamond can give rise to blue luminescence (e.g., with a peak centered at about 450 nm) and violet-blue luminescence (e.g., with a peak centered at about 415 nm). In some materials, one or more colors and intensity of luminescence may be preferentially created by controlling the number of NV, NVN, and/or N3 centers, and for some applications, one more colors of luminesce may be more desirable than other colors. In one example, ODMR may be used in connection with red luminescence, meaning that creation of NV centers may be desirable.

In connection with NV centers, at least two types of centers may be formed. In particular, red luminescence may be produced by NV centers that are negatively charged (NV⁻) as they can have a zero photon line (ZPL) at about 635 nm. In contrast, neutrally charged (NV⁰) centers can have a ZPL, at about 575 nm, and are thus closer to the green spectrum. In connection with magneto-optical properties, the red illumination of the NV⁻ centers may be particularly amendable for analysis by ODMR. As noted above, the technique may be powerful and capable of enhancing the sensitivity of spin resonance spectroscopy by several orders of magnitude. One aspect of the present disclosure thus relates to methods and diamond materials that preferentially control the creation of NV⁰ and NV⁻ centers when nanodiamond particles are produced (e.g., using HPHT sintering processes).

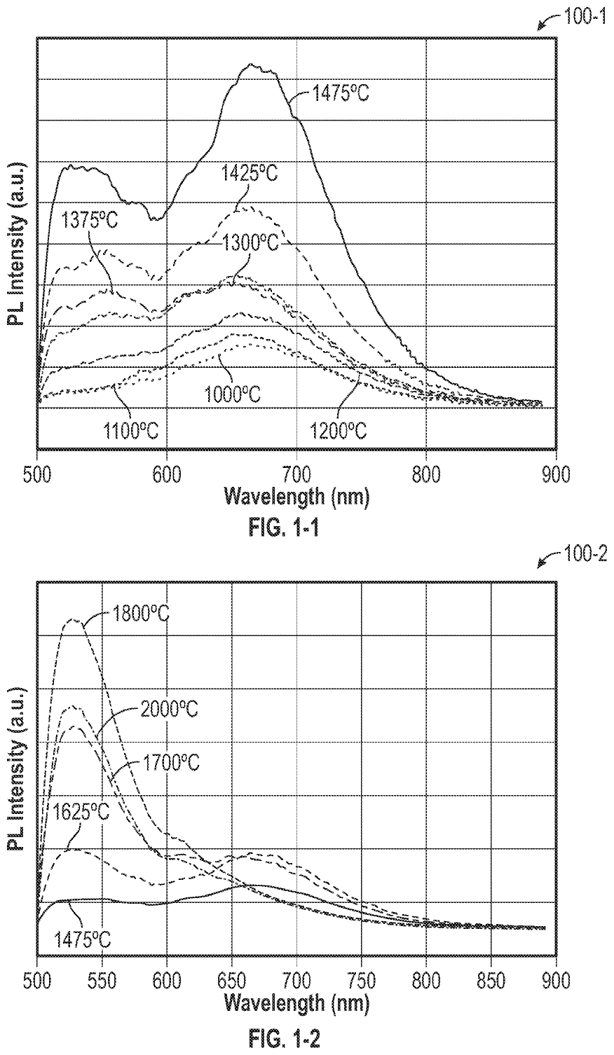

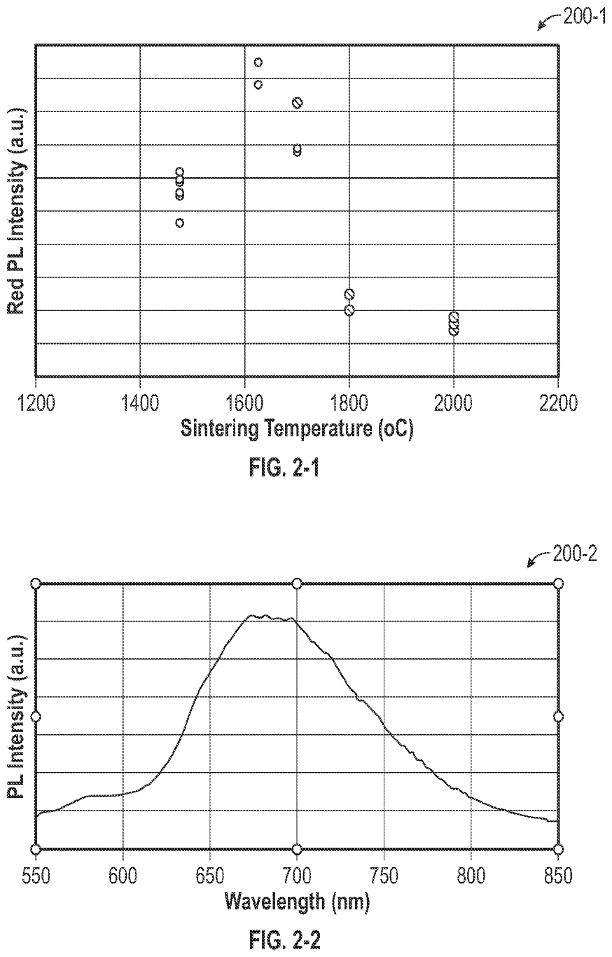

It has been found that the neutral to negative (NV⁰/NV⁻) ratio can depend on various factors, including the particle size and temperature for an HPHT sintering process. FIGS. 1-1 and 1-2 are, for instance, graphs 100-1 and 100-2 (collectively graphs 100) of the luminescent intensity vs. wavelength that show the effect of HPHT temperature on diamond grains without a catalyst material and subjected to 6.5 GPa cell pressure), across a series of different temperatures from 1000° C. to 2000° C. Specifically, the graphs illustrate the luminescent characteristics for diamond grains subjected to the HPHT process at 1000° C., 1100° C., 1200° C., 1300° C., 1375° C., 1425° C., 1475° C., 1625° C., 1700° C., 1800° C., and 2000° C.

The diamond grains subjected to each of the above-noted HPHT processes had an average particle size of 100 nm. As shown, the materials each have some level of luminescence across a wavelength of 500 nm to 900 nm, with peaks of green luminescence from about 520 nm to 570 nm (corresponding to NV⁰ and NVN centers) and peaks of red luminescence from about 620 nm to 720 nm (corresponding to NV⁻ centers). In this test it is apparent that both red and green luminescence can be created in the same diamond material depending on the HPHT temperature. Thus, it is understood that luminescent diamond as disclosed herein may be made to display one or more different wavelengths of luminescence, which may be optimized to suit a particular end-use application. Moreover, there is not always a direct correlation between red and green luminescence. For instance, from FIG. 1-2, the powders sintered at 1625° C. and 1700° C. have relatively lower intensity green luminescence as compared to powders sintered at 1800° C. and 2000° C., but have relatively higher intensity red luminescence. The line for the powder sintered at 1475° C. is the same as that from FIG. 1-1 and shows significantly lower green luminescence than the other powders in FIG. 1-2, but with some red luminescence to indicate NV⁻ were preferentially created, although lower than the powders sintered at 1625° C. and 1700° C.

The luminescence characteristics illustrated in FIGS. 1-1 and 1-2 (collectively FIG. 1) were produced by subjecting the HPHT processed diamond examples to 473 nm blue laser illumination as collected with a micro-spectrometer. These tests are representative of results from testing on a pellet formed after HPHT sintering or on powder materials. In these tests, it is shown that the HPHT temperature conditions of 1000° C. to 2000° C. preferentially produced NV⁻ luminescence, with the HPHT temperature conditions of 1800° C. to 2000° C. exhibiting relatively lower luminescence due to NVN centers as the temperatures above 1800° C. seem to convert NV centers to NVN centers and weaken the red intensity, which is shown as declining red wavelengths. At lower temperatures of 1000° C. to 1475° C., peaks of red luminescence are still apparent, albeit at lower intensities which can correspond to higher numbers of NV⁰ centers. In this example, temperatures between 1600° C. and 1750° C. appear to particularly be effective at preferentially producing NV⁻ centers over NV⁰ centers and NVN centers, which increases the red luminescence intensity.

FIGS. 2-1 and 2-2 (collectively FIG. 2) are graphs 200-1, 200-2 (collectively 200) that further illustrate the effect of sintering temperature on the creation of NV centers (and particularly the preferential creation of NV⁻ centers) that result in red luminescence. FIG. 2-1 shows the luminescence intensity of a diamond powder when sintered at temperatures between 1475° C. and 2000° C. when excited by a 532 nm green laser. The diamond material was formed from diamond grains having an average particle size of 100 nm. FIG. 2-2 is a chart of the intensity of the material sintered at 1475° C., and over wavelengths between 550 nm and 850 nm. The test producing the charts in FIGS. 2-1 and 2-2 demonstrates that while intensity of red luminescence increased for the material sintered at 1475° C. (reflecting creation of both NV⁰ and NV⁻ centers), the diamond materials sintered in a temperature range between 1600° C. and 1750° C. had even higher red luminescence intensity, showing preferential creation of even more NV⁻ centers. In contrast, red intensity at 1800° C. and 2000° C. dropped significantly, likely as a result of increased creation of NVN centers.

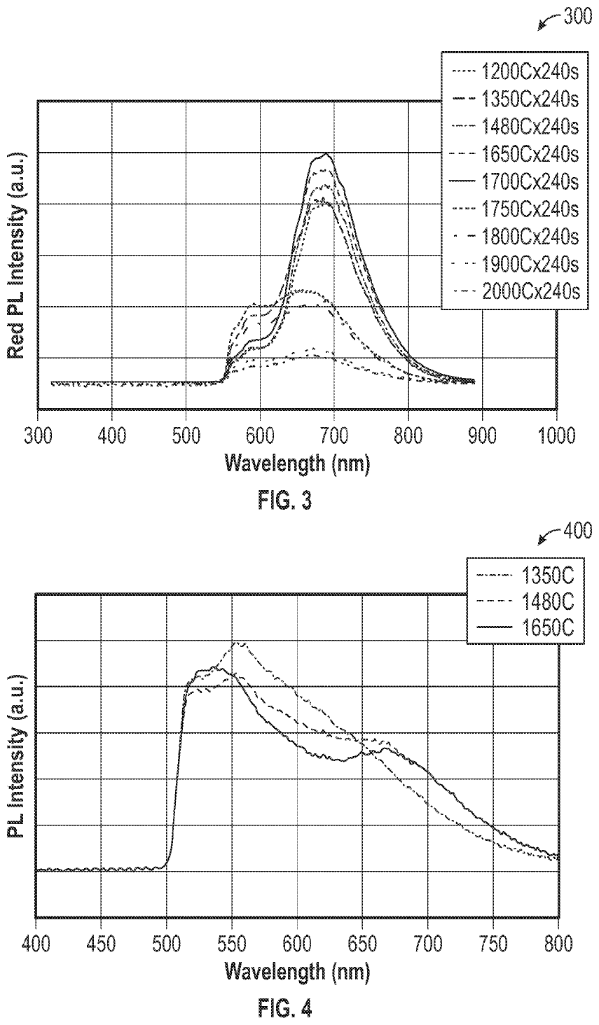

FIGS. 3 to 5 are further graphs 300, 400, 500 of examples of the effects of temperature on red luminescence intensity, but use different particle sizes than hose used for the tests reflected in the graphs 100, 200 of FIGS. 1 and 2. FIGS. 3 and 4, for instance, are graphs 300, 400 produced from analysis of diamond powder having an average grain size of 50 nm and directly sintered by HPHT methods at temperatures between 1200° C. and 2000° C. In FIG. 3, the luminescence intensity of the various materials is shown of across the visible spectrum (380 nm to 750 nm), as well as across portions of ultraviolet (300 nm to 380 nm) and near-infrared (750 nm to 875 nm) spectrums. All intensities were measured when exciting the materials with a 532 nm green laser.

The 50 nm particle size shows results similar to those for the 100 nm particles, with particularly significant intensity in the red wavelengths when the sintering temperature is between 1650° C. and 1750° C. However, significant red intensity increases are also seen as low as 1480° C. and as high as 1800° C. Thus, when compared with the test used to produce FIG. 2-2, the smaller particle size appears to allow materials to have increased red intensity (corresponding to preferential NV⁻ center creation) at a broadened temperature range up to 1800° C. However, further increases of temperature to 1900° C. and 2000° C. show significant decreases of red intensity, similar to those of prior examples. Lower temperatures of 1200° C. to 1350° C. also show some peak in red luminescence intensity above those at temperatures above 1900° C., which reflects some preferential creation of NV⁻ centers, but the peaks are significantly lower than those in sintered at 1480° C. to 1800° C., indicating that higher numbers of NV⁰ centers are still created. In particular, with materials sintered at temperatures below 1400° C., the intensity from NV⁰ centers (ZPL at about 575 nm) is rather close to the intensity from the NV⁻ centers (with ZPL at about 635 nm). However, after increasing the sintering temperature, more NV⁻ centers form and the photoluminescence from NV⁻ centers dominates the luminescence spectra.

When the materials are excited with a 473 nm blue laser, the differences in the spectra can also be detected for the samples, including those sintered from 1350° C. to 1650° C. as shown in the graph 400 of FIG. 4.

FIG. 5 is a further graph 500 showing the red intensity of nanodiamond materials after HPHT sintering at a variety of different temperatures. The graph 500 in FIG. 5 reflects tests performed on different materials where the average particle size was 25 nm, and which were excited with a 532 nm green laser. As shown, sintering at temperatures between 1600° C. and 1750° C. produced higher red luminescence corresponding to creation of NV⁻ centers, with temperatures of 1600° C. to 1700° C. being particularly effective across the red spectrum.

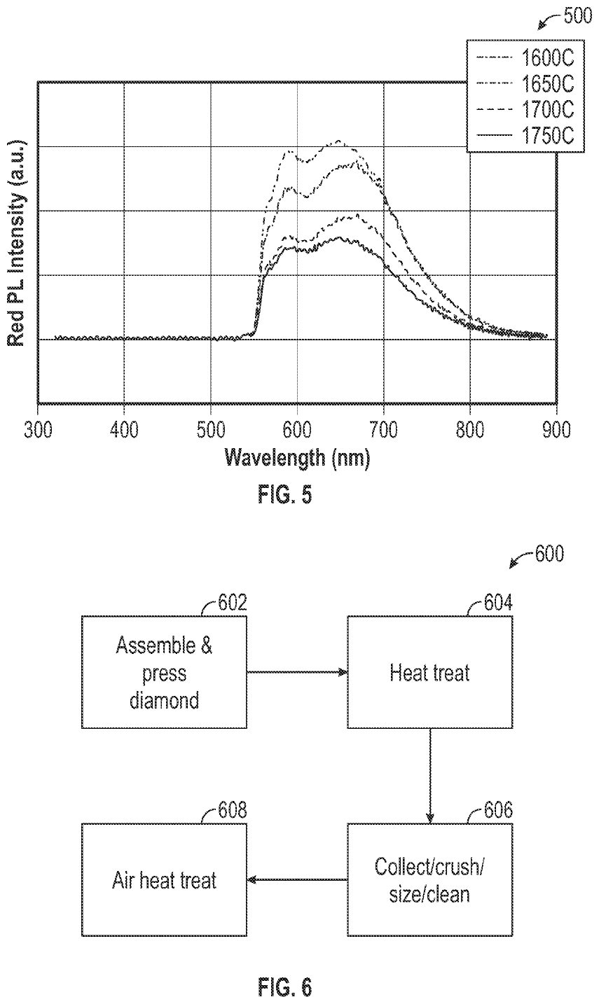

FIG. 6 is a block diagram 600 illustrating processing that may be used for making luminescent diamond. In some embodiments, the processes may be carried out in a series that include two or more of the steps that are illustrated. In a first process 602, materials useful for making the luminescent diamond are combined and assembled in the manner discussed herein, which may or may not include the use of a catalyst material, and that includes subjecting the assembled or combined materials to an HPHT process, which may or may not result in the formation of a fully-sintered diamond compact. In some embodiments, the first process 602 creates vacancies/centers in the resulting diamond material for forming nitrogen (NV⁰, NV⁻, NVN, and/or N3) as discussed herein. In a second optional process 604 the diamond material produced from the first process 602 is subjected to a heat treatment process. The heat treatment optionally occurs under vacuum conditions. Example heat treatments can include an annealing process which is optionally carried out at a temperature of above 500° C.

With reference to the luminescence intensity results, in some embodiments, pressing the diamond material in the first step 602 and/or performing the heat treatment in step 604 can increase the luminescence intensity of the diamond material (e.g., by increasing the NV count for red intensity, including the ratio of NV centers to NVN centers and/or the ratio of NV⁻ to NV⁰ centers). In a third optional process 606, the diamond material from process one 602 or process two 604 is collected or reduced in size by crushing, milling, grinding, or other sizing technique. Where the particles are crushed, ground, milled, etc., the size of diamond particles formed during this third step 606 may depend on the particular end-use application for the luminescent diamond material. During this third process 606, the diamond material can be converted to powder. In some embodiments, reducing the size of the diamond material increases the luminescence intensity of the diamond material (e.g., by 3 to 4 times due to the increased surface area of the resulting powder).

Optionally, the third process 606 can collect or produce powder without crushing, grinding, milling, etc. For instance, an HPHT process in step 602 may be performed with a pressure transfer media that does not promote diamond-to-diamond intercrytstalling bonding, and which does not act as a catalyst for diamond synthesis. For instance, sodium chloride (NaCl) may be used to transfer pressure between diamond grains and deform them as discussed here to create NV, NVN, or N3 vacancies. In some cases, the resulting material may remain in a granular or powder form that can be collected without milling, grinding, etc. For instance, raw precursor diamond powder with an average size of 1 nm to 90 nm (e.g., 1 nm to 30 nm, 30 nm to 90 nm, etc.) may undergo an HPHT process with a pressure transfer media, and result in processed diamond powder having a similar average size. In some cases the size may be slightly reduced, or the relative proportions may be changed (e.g., spherical diamond grains into elliptical diamond grains).

In a fourth optional process 608, the diamond material from process one 602, process two 604, or process three 606 is subjected to an air heat treatment (e.g., an oxidizing heat treatment). In some embodiments, the air heat treatment whitens surfaces of the diamond material which is believed to be due to the formation of oxygen-terminated diamond bonds. In some embodiments, subjecting the diamond material to this fourth process 608 increases the luminescence intensity by up to about 10 times. In some embodiments, luminescence diamond materials as disclosed herein may be formed according to one or more of these processes, and in some embodiment using all of these processes in sequential order depending on the type and/or degree of luminescence intensity called for by the particular end-use application.

In some embodiments where the luminescent diamond resulting from the HPHT process is in the form of a metal PCD (e.g., cobalt PCD), it may be desired to treat the sintered PCD body to completely or partially remove the metal material therefrom, which may be done by leaching process or other process known in the art to remove the metal catalyst from the PCD to enable use in such those applications where the presence of metal is not desired or permitted or practical (e.g., in biological applications). Also, removing the catalyst material from the PCD weakens the structure of the sintered body making it easier to crush and reduce in size.

In some embodiments of luminescent diamond as disclosed herein that is formed using a carbonate catalyst, e.g., carbonate PCD, is that such a metal free PCD is metal free and thus may be used without the need for any catalyst removal in biological or other end-use applications. It may be helpful in some embodiments to use magnetic separation techniques to ensure that the luminescent diamond material is sufficiently free of metallic catalysts. In some embodiments of luminescent diamond provided in the form of carbonate PCD, a level of luminescence intensity that is substantially higher that than of cobalt PCD is obtained, which may result from the higher levels of temperature and pressure used in the HPHIT sintering process employed in carbonate PCD, as well as a relative transparency increase and reduced opacity of the carbonate PCD as contrasted with the cobalt PCD as noted above.

Luminescent diamond as disclosed herein may be sized after the HPHT consolidation process to facilitate use in applications calling for smaller-sized diamond particles, e.g., nano-sized particles, such as in biological applications as discussed above. Accordingly, after the luminescent diamond has been consolidated by HPHT processing, it is subjected to a size reducing treatment for purposes of breaking the diamond material into smaller-sized diamond pieces or grains. In some embodiments, the luminescent diamond may be treated to reduce the size to an average diameter of 1 nm to 1 mm, or from 5 nm to 200 μm or the like. Examples of useful average particle size ranges include but are not limited to 5 nm to 100 nm, 100 nm to 200 nm, 200 nm to 1000 nm, 500 nm to 20 μm, or 20 μm to 200 μm. In some embodiments it may be useful for the average particulate size to be 1 μm or larger. The particular process that is used for reducing the size of the diamond material resulting from HPHT processing can and will vary depending on the particular material (e.g., whether the diamond material is in the form of sintered PCD, partially-sintered PCD, or mechanically-combined diamond grains) and/or the resultant size desired after processing.

In some embodiments, the diamond material may be crushed by high-velocity impact with a high-strength target (e.g., one made from tungsten carbide or the like), or by impact with another diamond material (e.g., self-impact under high-velocity conditions). In some embodiments such as where the diamond material is to be used in biological applications it may be desired that the diamond material be reduced to nanosized pieces or particles. The process of reducing or sizing the diamond material may be carried out at an elevated temperature or ambient temperature condition in the event that such helps to make the process easier or in the event that such causes the diamond material to undergo further plastic deformations to further increase luminescent activity and luminescence intensity. Sorting by magnetic or other mechanical technique may be used for purposes of isolating the luminescent diamond particles with cobalt inclusions from luminescent particles free of cobalt inclusions. In some end use applications, the shape of the resulting particulate may be relevant as some cellular structures are sensitive to sharp edges such as those created with fragmented diamond crystals. In these applications, it may be desirable to employ detonation nanodiamond as the starting material as these particulates are essentially spherical in shape. In some embodiments, treating the material in an oxidizing environment as described has been shown to remove 50% or more of the diamond crystals under some conditions, which can be employed to remove sharp edges and increase the sphericity of the particulates. In the powder sizing mentioned above, an adequate definition of particle size can be achieved by employing the approach of equivalent circle of equal projection area as defined by D_{EQPC}=2\sqrt{A/π}, where D_{EQPC} is the diameter of a circle with the same projected area A as the particle of interest.

As noted herein, during the process of reducing the diamond material to desired diamond particle sizes (e.g., nano-sized particles), the diamond material can undergo further plastic deformations or fracture (e.g., beyond that which occurred during the HPHT process), causing the luminescent activity and the luminescence intensity of the resulting diamond material to further increase. Thus, the resulting sized diamond particles can have a level of luminescence intensity that is greater than that of the diamond material after HPHT processing. Further, if an intermediate treatment such as those discussed herein is carried out between HPHT processing and sizing, there may be two increases in luminescent activity/intensity between the diamond material in a consolidated state during after HPHT processing and the diamond particles after the reducing or sizing process.

It is to be understood that the amount of luminescence intensity increase may vary depending on such factors as the particular type of luminescent diamond material, the size of grains in precursor diamond materials, the technique or process used for reducing the processed diamond material, the ultimate size of the luminescent diamond particles, and other process treatments employed such as heat treatment in vacuum conditions and/or air heat treatment. In addition to displaying a greater luminescence intensity than that of conventional or other luminescent nanodiamond, luminescent diamond as described herein main maintain its luminescence intensity for a longer duration of time than that of the conventional luminescent nanodiamond.

As discussed herein, precursor diamond materials may have a variety of sizes, which can affect at least the luminescence intensity. In some cases, the size of the precursor materials in combination with the temperature of an HPHT process affect the luminescence intensity. Examples of useful average particle size ranges for precursor diamond materials, but are not limited to materials between 1 nm and 1 mm, along with any range having lower and upper end points therebetween. In some specific examples, the average size of grains in precursor materials may be from 1 nm to 100 nm, from 1 nm to 30 nm, from 30 nm to 90 nm, from 100 nm to 200 nm, from 100 nm to 45 μm, from 200 nm to 1000 nm, from 500 nm to 20 μm, or from 20 μm to 200 μm. In some embodiments it may be useful for the average grain size to be 1 μm or larger, while in other embodiments it may be useful for the average grain size to be less than 100 nm (e.g., less than 90 nm).

Various temperatures may also be used during the HPHT process. In some embodiments, the maximum sustained temperature is between 1000° C. and 2500° C., although any range with lower and upper end points therebetween may also be used. For instance, a suitable range may include lower and upper values including any of 1000° C., 1100° C., 1200° C., 1300° C., 1400° C., 1425° C., 1450° C., 1475° C., 1500° C., 1525° C., 1550° C., 1575° C., 1600° C., 1625° C., 1650° C., 1675° C., 1700° C., 1725° C., 1750° C., 1775° C., 1800° C., 1825° C., 1850° C., 1875° C., 1900° C., 1925° C., 1950° C., 1975° C., 2000° C., 2025° C., 2050° C., 2075° C., 2100° C., 2150° C., 2200° C., 2250° C., 2300° C., 2350° C., 2400° C., 2450° C., 2500° C., or any value therebetween. Thus, by way of illustration, a temperature of an HPHT process in some embodiments may be in a range from 1000° C. to 2500° C., from 1450° C. to 1900° C., from 1475° C. to 1850° C., from 1575° C. to 1775° C., from 1600° C. to 1800° C., from 1600° C. to 1750° C., or others as produced with the above endpoints.

As noted herein, luminescent diamond may be formed using a non-catalyst material that does not promote intercrystalline diamond bonding during the HPHT process to result in a body that is free (e.g., substantially free) of intercrystalline diamond bonding. Such materials may be considered pressure transfer media. As used herein, pressure transfer media refers to materials that operate to facilitate diamond-to-diamond mechanical combination during the HPHT process. Thus, in contrast to materials that promote high intercrystalline diamond-to-diamond bonding. Thus, pressure transfer media promotes weak or no intercrystalline diamond-to-diamond bonding, with instead a preference for mechanical combination. Examples of pressure transfer media materials useful for making luminescent diamond include and are not limited to carbonates, nitrates, sulfates, phosphates, chlorates, perchlorates, acetates, chromates, oxalates, sulfides, ammonium compounds, hydroxides, oxides, cyanides, cyanates, dichromates, halides, chlorides, fluorides, or combinations thereof. The pressure transfer media may be selected from materials that promote diamond growth but do not promote high intercrystalline diamond-to-diamond bonding, such as sodium carbonate (Na₂CO₃) and other alkali metal carbonate materials or compounds, or other functionally similar materials.

The pressure transfer media may be selected from materials that are not a catalyst for diamond synthesis such as sodium chloride (NaCl) or sodium fluoride (NaF) and other chloride or fluoride materials or compounds, or other functionally similar materials. In some embodiments, it is desired that material selected as the pressure transfer media be water soluble, acid soluble, or base soluble to facilitate removal from the luminescent diamond formed by HPHT processing by water, acid, or base washing. The pressure transfer media can be a liquid or a solid at room temperature and at one atmosphere. In some embodiments, the pressure transfer media may be provided in the form of a solid for easy handling during loading of the HPHT container. Further, while different types of pressure transfer media have been described, it is to be understood that the pressure transfer media that is used may be of a single phase, such as NaCl or Na₂CO₃, or the pressure transfer media may comprise two or more phases of different materials, such as NaCl—Na₂CO₃ or NaCl—KCl—LiCl mixtures or the like. The use of a two or more phase pressure transfer media mix composition enables one to widely vary and control the desired melting point of the pressure transfer media during the HPHT process, e.g., to ensure that the pressure transfer media is in a liquid state during HPHT processing to fill gaps (e.g., most or all gaps) between the diamond particles to thereby minimize or eliminate diamond surface graphitization.

In some embodiments, luminescent diamond may be made in a manner similar that that disclosed above, wherein a volume of nano-or micro-sized diamond grains or powder is premixed with a pressure transfer media such as Na₂CO₃, NaCl, and/or NaF powder. When subjected to the HPHT process, the pressure transfer media functions to transfer the pressure to the diamond particles and also fills voids between the diamond particles to minimize or eliminate diamond graphitization. During the HPHT process, a shear load is applied to the diamond particles through diamond-to-diamond particle point contacts, which shear load functions to cause plastic deformation at high temperatures that creates the NV, NVN, and/or N3 defects/centers. In some embodiments, the volume percent of the precursor diamond grains is controlled to ensure the generation of such point contacts and resulting shear load. In some embodiments, the amount of the precursor diamond grains used is greater than 20 volume percent, and in some embodiments, greater than 50% by volume based on the total volume of the diamond grain and pressure transfer media mixture. In some embodiments, the amount of pressure transfer media may also be controlled to ensure that it fills the open space between diamond particles to minimize or prevent diamond surface graphitization at high temperatures. In some embodiments, the amount of the pressure transfer media used is greater than 5 volume percent, and in some embodiments greater than 10% by volume based on the total volume of the diamond grain and pressure transfer media mixture.

While the method of making luminescent diamond disclosed above involves the premixing of diamond grains and the pressure transfer media, it is to be understood the diamond grains can be loaded into the HPHT container (e.g., a refractory metal capsule), without being premixed with the pressure transfer media. In such example, the pressure transfer media may be provided in the form of one or more layers or bodies placed adjacent one or more layers of diamond grains inside of the container. At elevated temperature during the HPHT process, the pressure transfer media can melt and infiltrates into the volume of diamond grains by the applied pressure. In some embodiments, the layer or body of pressure transfer media is of sufficient volume to ensure full infiltration of the diamond grain volume.

For use of the luminescent diamond as disclosed herein in certain downstream applications such as biological uses, it may be desired that the luminescent diamond particles, e.g., nanodiamond, be further treated or functionalize to adapt the material for its intended use. The manner and type of treatment that may be used to functionalize the luminescent diamond material as disclosed herein is understood to vary depending on the particular end-use application. However, an example functionalizing process may be one that involves oxygen termination along the diamond surface to render the diamond surface hydrophilic, and may be established through a range of surface oxidation procedures. Such oxygen termination functionalization may include providing a mixture of ═O, —OH, —COOH, or —C—O—C— groups on the surface. Other surface terminations may include hydrogen termination, halogenation, thermal annealing to create double bonds, and reduction to OH termination. A further type of functionalization may involve the grafting or attachment of certain molecules to the surface of the diamond treated as treated in the manner noted to promote such attachment, where such molecules are selected to readily react with different biomolecules. A still further type of functionalization may include biolabeling which may take place though an electrostatic (non-covalent) or covalently bonded attachment between the diamond particle and biomolecules. These are but a few methods in which luminescent diamond as disclosed herein may be functionalized for use in biological applications, and it is to be understood that other known approaches and techniques useful for functionalizing luminescent diamond for a particular biological use is within the scope and spirit of this disclosure.

Although but a few example embodiments of luminescent diamond have been described in detail above, those skilled in the art will readily appreciate that many modifications are possible in the example embodiments without materially departing from this invention. For example, luminescent diamond as disclosed herein has been presented in the context of a biological end-use application and/or in connection with optically detected magnetic resonance processes. It is to be understood that luminescent diamond as disclosed herein may be used in end-use applications other than biological or with detection methods other than optically detected magnetic resonance, where a desired improved level of luminescence intensity is useful or beneficial. Other potential uses of luminescent diamond include but are not limited to usage in magnetic sensors, high resolution thermography, microscopic sensor arrays, anti-counterfeiting measures, ion concentration monitoring, membrane potential measurement, optical trapping, quantum computing, and strain/pressure sensors. Therefore, it is understood that luminescent diamond as disclosed herein is not intended to be limited to one particular end use application or detection mechanism. It should be understood that references to “one embodiment,” “an embodiment,” “an example” of the present disclosure or the like are not intended to be interpreted as excluding the existence of additional embodiments that also incorporate the recited features. For example, while the features of the materials and processes herein are shown or described, they may also be combined. Indeed, any element or feature described in relation to an embodiment herein may be combinable with any element or feature of any other embodiment described herein.

Certain descriptions or designations of components as “first,” “second,” “third,” and the like are used to differentiate between identical components or between components which are similar in use, structure, or operation. Such language is not intended to limit a component to a singular designation or require multiple components. As such, a component referenced in the claims as the “first” component may be the same or different than a component that is referenced in the specification as a “component” or even as a “first” component, and a claim may include a “first” component without requiring the existence of a “second” component.

Furthermore, while the description or claims may refer to “an additional” or “other” element, feature, aspect, component, or the like, it does not preclude there being a single element, or more than one, of the additional clement. Where the claims or description refer to “a” or “an” element, such reference is not be construed that there is just one of that element, but is instead to be inclusive of other components and understood as “at least one” of the element. It is to be understood that where the specification states that a component, feature, structure, function, or characteristic “may,” “might,” “can,” or “could” be included, that particular component, feature, structure, or characteristic is provided in certain embodiments, but is optional for other embodiments of the present disclosure. The terms “couple,” “coupled,” “connect,” “connection,” “connected,” “in connection with,” and “connecting” refer to “in direct connection with,” or “in connection with via one or more intermediate elements or members.” Components that are “integral” or “integrally” formed include components made from the same piece of material, or sets of materials, such as by being commonly molded or cast from the same material, in the same molding or casting process, or commonly machined from the same piece of material stock. Components that are “integral” should also be understood to be “coupled” together.

Any numbers, percentages, ratios, or other values stated herein are intended to include that value, and also other values that are “about” or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

The terms “approximately,” “about,” and “substantially”, if used herein or in the claims, represent an amount close to the stated amount that is within standard manufacturing or process tolerances, or which still performs a desired function or achieves a desired result. For example, the terms “approximately,” “about,” and “substantially” may refer to an amount that is within less than 5% of, within less than 1% of, within less than 0.1% of, and within less than 0.01% of a stated amount.

Although various example embodiments have been described in detail herein, those skilled in the art will readily appreciate in view of the present disclosure that many modifications are possible in the example embodiments without materially departing from the present disclosure. Accordingly, any such modifications are intended to be included in the scope of this disclosure. For instance, although the present disclosure relates specifically to formation of nitrogen vacancies and centers (e.g., NV, NVN, N3), embodiments of the present disclosure may expand to formation and optimization of materials having other luminescent centers. For instance, materials with silicon (Si) vacancies may be similarly formed and treated. Additionally, while the disclosure herein contains many specifics, these specifics should not be construed as limiting the scope of the disclosure or of any of the appended claims, but merely as providing information pertinent to one or more specific embodiments that may fall within the scope of the disclosure and the appended claims. Any described features from the various embodiments disclosed may be employed in combination.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

The Abstract at the end of this disclosure is provided to allow the reader to quickly ascertain the general nature of some embodiments of the present disclosure. It is submitted with the understanding that it will not be used to interpret or limit the scope or meaning of the claims.

The Appendix included herewith is fully incorporated into this disclosure, in its entirety, for all purposes.

1. A method for making luminescent diamond comprising:
subjecting a volume of precursor diamond grains to a high-pressure/high-temperature (HPHT) condition at an elevated temperature between 1600° C. and 1800° C., and thereby causing the diamond grains to undergo plastic deformation to preferentially produce negatively charged nitrogen vacancy (NV⁻) defects in the diamond grains,
wherein the resulting diamond material displays a level of luminescence intensity in a red wavelength spectrum that is greater than that of the precursor diamond grains.

2. The method of claim 1, wherein the level of luminescence intensity in the red wavelength spectrum is greater than that of the precursor diamond grains when subjected to an elevated temperature between 1000° C. and 1450° C. or between 1900° C. and 2000° C.

3. The method of claim 1, where the resulting diamond material has a higher ratio of NV⁻ to neutral nitrogen vacancy (NV⁰) defects than the precursor diamond grains subject to the elevated temperature of between 1000° C. and 1450° C. and a higher ratio of NV defects to NVN defects than the precursor diamond grans subjected to the elevated temperature between 1900° C. and 2000° C.

4. The method of claim 1, wherein the resulting diamond material is substantially free of intercrystalline bonded diamond.

5. The method of claim 1, wherein the volume of precursor diamond grains is subjected to the HPHT condition in the presence of a pressure transfer media.

6. The method as recited in claim 5, wherein the pressure transfer media does not promote intercrystalline diamond bonding during the HPHT condition.

7. The method as recited in claim 5, wherein the pressure transfer media is selected from the group consisting of carbonates, nitrates, sulfates, phosphates, chlorates, perchlorates, acetates, chromates, oxalates, sulfides, ammonium compounds, hydroxides, oxides, cyanides, cyanates, dichromates, halides, chlorides, fluorides, and combinations thereof.

8. The method as recited in claim 5, wherein the pressure transfer media is mixed with the volume of diamond grains before the HPHT condition.

9. The method as recited in claim 5, wherein the pressure transfer media is placed adjacent the volume of diamond grains before the HPHT condition, and wherein the pressure transfer media melts and fills the interstitial pores within the volume of diamond grains during the HPHT condition at the elevated temperature.

10. The method as recited in claim 5, wherein after the HPHT condition, the resulting diamond material comprises greater than 20% by volume diamond and greater than 5% by volume pressure transfer media based on a total volume of the resulting diamond material.

11. The method as recited in claim 5, wherein after the HPHT condition, the resulting diamond material comprises greater than 50% by volume diamond and greater than 10% by volume pressure transfer media based on a total volume of the resulting diamond material.

12. The method as recited in claim 5, wherein the pressure transfer media is selected from the group consisting of water soluble materials, acid soluble materials, and base soluble materials.

13. The method as recited in claim 1, wherein after the HPHT condition, the resulting diamond material comprises diamond particles in a powder form or which are mechanically interlocked together and separable without a milling, grinding, or crushing process.

14. The method as recited in claim 1, further comprising:
after subjecting the volume of precursor diamond grains to the HPHT condition, washing the resulting diamond material and thereby removing all or a portion of the pressure transfer media therefrom.

15. The method as recited in claim 1, wherein the elevated temperature is between 1600° C. and 1750° C., and an average size of the precursor diamond grains is between 50 nm and 5 μm.

16. A luminescent diamond material comprising:
diamond particles that are mechanically interlocked together and combined with a pressure transfer media,
wherein the luminescent diamond material includes diamond grains that have undergone plastic deformation through a high-pressure/high-temperature (HPHT) process, and wherein the luminescent diamond material displays a level of red luminescence greater than that of precursor diamond material used to form the luminescent diamond material as a result of a higher ratio of negatively charged nitrogen vacancies (NV⁻) to either or both of neutral charge nitrogen vacancies (NV⁰) and NVN defects.

17. The luminescent diamond material as recited in claim 16, wherein the HPHT process includes a temperature condition between 1600° C. and 1750° C.

18. The luminescent diamond material as recited in claim 17, wherein the diamond particles have an average particle size between 100 nm and 45 μm.

19. The luminescent diamond material as recited in claim 16, wherein the HPHT process includes a temperature condition between 1475° C. and 1800° C.

20. The luminescent diamond material as recited in claim 19, wherein the diamond particles have an average particle size between 30 nm and 90 nm.

21. The luminescent diamond material as recited in claim 19, wherein the diamond particles have an average particle size 1 nm and 30 nm.

22. The luminescent diamond material as recited in claim 16, the pressure transfer media being a material that does not promote intercrystalline bonding of precursor diamond grains during the HPHT process.

23. The luminescent diamond material as recited in claim 16, wherein the pressure transfer media is selected from the group consisting of carbonates, nitrates, sulfates, phosphates, chlorates, perchlorates, acetates, chromates, oxalates, sulfides, ammonium compounds, hydroxides, oxides, cyanides, cyanates, dichromates, halides, chlorides, fluorides, water soluble materials, acide soluble materials, base soluble materials, and combinations or mixtures thereof.

24. The luminescent diamond material as recited in claim 16, wherein the diamond particles are substantially free of intercrystalline bonded diamond.

25. The luminescent diamond material as recited in claim 16, comprising greater than 50% by volume diamond and greater than 10% by volume pressure transfer media based on the total volume of the luminescent diamond material.

26. The luminescent diamond material as recited in claim 16, further comprising a total graphite content of less than 5% by weight after being made by the HPHT process, without further treatment.

27.-28. (canceled)
